(19) United States
(12) Patent Application Publication
(10) Pub. No.: US 2023/0418989 A1
(43) Pub. Date: Dec. 28, 2023

(54) PROACTIVE AUDIBLE SOUND REVERBERATION MITIGATION FOR PREDICTED USER EXPERIENCE

(71) Applicant: INTERNATIONAL BUSINESS MACHINES CORPORATION, ARMONK, NY (US)

(72) Inventors: Tiberiu Suto, Franklin, NY (US); Martin G. Keen, Cary, NC (US); Jeremy R. Fox, Georgetown, TX (US); Sarbajit K. Rakshit, Kolkata (IN)

(21) Appl. No.: 17/809,295

(22) Filed: Jun. 28, 2022

(51) Int. Cl. G06F 30/17; B25J 9/16; G06T 7/70

(52) U.S. Cl. CPC G06F 30/17; B25J 9/1633; G06T 7/70; G06T 2207/10016

(57) ABSTRACT

In an approach for utilizing digital twin simulation for automatically mitigating noise, a processor generates a digital twin of an environment. The digital twin simulates vibration within the environment based on equipment and activities within the environment that are simulated by the digital twin. A processor determines how vibration is propagated within the environment based on the simulated vibration generated by the digital twin. A processor generates a plan for mitigating the vibration for a user within the environment.

### BACKGROUND

The present disclosure relates generally to the field of utilizing digital twin simulations for automatically mitigating noise, and more particularly to proactive audible sound reverberation mitigation for predicted user experience.

A digital twin is a virtual representation of an object or system that spans its lifecycle, is updated from real-time data, and uses simulation, machine learning and reasoning to help decision-making. A highly complex virtual model may be the exact counterpart (or twin) of a physical thing. For example, the “thing” could be a car, a building, a bridge, or a jet engine. Connected sensors on the physical asset collect data that can be mapped onto the virtual model. Anyone looking at the digital twin can now see crucial information about how the physical thing is doing out there in the real world.

In an industrial shop floor, there can be several different types of noises in the surrounding generated from various machines and activities, for example, friction among machine parts, vibration of machine parts and equipment etc. There could be sources of noise in the surrounding. Noise can be generated from overhead machines, like overhead crane. At any time, noise could be coming from multiple directions while the activities are being performed and the location of noise generation can vary from time to time, activity to activity and machine to machine, etc. Vibration from any structure or machine may cause noise. Over a period of a time, because of wear and tear, loose fitting and unbalance force, vibration may be generated and hence may generate noise. At the same time, way of performing activities can also generate noise.

### SUMMARY

Aspects of an embodiment of the present disclosure disclose an approach for utilizing digital twin simulation for automatically mitigating noise. A processor generates a digital twin of an environment. The digital twin simulates vibration within the environment based on equipment and activities within the environment that are simulated by the digital twin. A processor determines how vibration is propagated within the environment based on the simulated vibration generated by the digital twin. A processor generates a plan for mitigating the vibration for a user within the environment

### BRIEF DESCRIPTION OF THE DRAWINGS

FIG. 1 is a functional block diagram illustrating a reverberation mitigation environment, in accordance with an embodiment of the present disclosure.

FIG. 2 is a flowchart depicting operational steps of a reverberation mitigation module within a computing device of FIG. 1, in accordance with an embodiment of the present disclosure.

FIG. 3 illustrates an exemplary operation environment of the reverberation mitigation module within the computing device of FIG. 1, in accordance with an embodiment of the present disclosure.

FIG. 4 illustrates exemplary functional diagram and operational steps of the reverberation mitigation module within the computing device of FIG. 1, in accordance with an embodiment of the present disclosure.

FIG. 5 is a block diagram of components of the computing device of FIG. 1, in accordance with an embodiment of the present disclosure.

### DETAILED DESCRIPTION

The present disclosure is directed to systems and methods for utilizing digital twin simulations for automatically mitigating noise generated in industrial floors. The digital twin simulations may generate identified noise profile of the industrial floors for deploying noise cancellation modules.

Embodiments of the present disclosure recognize a need for mitigating noise generated in industrial floors. For example, if workers are working continuously in a noisy surrounding, there can be various health hazards for the workers due to exposure to high ambient noise levels. The location and direction of noise generation can keep on changing in any industrial floor and may making the noise very uncomfortable for the workers. In some cases, wearing noise reduction accessories all the time may not be a feasible solution. Sound absorbing synthetic materials may be available at present, but can only be installed in certain types of environments, e.g., theatres or conference halls, and not in a factory type establishment such as a shop floor.

Embodiments of the present disclosure disclose methods and systems for utilizing digital twin simulations for automatically mitigating noise generated in industrial floors, wherein the digital twin simulations may generate identified noise profile of the industrial floors for deploying noise cancellation modules. Embodiments of the present disclosure disclose generating a digital twin of an environment. The digital twin may be configured to simulate vibration within the environment based on equipment and activities within the environment that are simulated by the digital twin. Embodiments of the present disclosure disclose determining how vibration is propagated within the environment based on the simulated vibration generated by the digital twin. Embodiments of the present disclosure disclose generating a plan for mitigating the vibration for users within the environment. The plan for mitigating the vibration may include determining at least one location to deploy a noise cancellation module within the environment. The plan for mitigating the vibration may include deploying a robot configured to attenuate the vibration in a determined location.

Embodiments of the present disclosure disclose utilizing the digital twin and the real physical environment to evolve the ability to secure the noise cancelation. Embodiments of the present disclosure utilizing an autonomous robotic means to secure the cancellation processing. Embodiments of the present disclosure disclose providing a proactive action to be taken within the clear noise cancelation amelioration processing. Embodiments of the present disclosure disclose using machine learning techniques to determine anticipated worker activities that will generate noise and to determine the propagation of sound from the source of noise to other workers in vicinity which will result in exposure at an acceptable level. Embodiments of the present disclosure disclose determining a robot placement to attenuate the sounds via different techniques depending on calculation of which will give the best noise reduction. Additionally, when no satisfactory noise reduction can be achieved under current environment, equipment may display a warning and, in some embodiments, a lockout. Embodiments of the present disclosure disclose utilizing the digital twin simulation from piezoelectric sensor analysis. Embodiments of the present disclosure disclose utilizing a piezoelectric sensor analysis based on digital twins and the proactive response action(s) derived within. Embodiments of the present disclosure disclose creating an actionable processing plan for a system and model through the utilization of a color spectrum infused processing approach.

Embodiments of the present disclosure disclose a digital twin with vibration infused simulation. For example, while constructing or repairing any industrial floor, embodiments of the present disclosure disclose using a digital twin computing system to simulate generation of vibrations from various parts of the industrial floor. This may include structures, machines, and various activities. Accordingly, the digital twin may generate a vibration pattern on a real time basis and aid in identifying the exact location of resonance, type of resonance, etc. Embodiments of the present disclosure disclose using a digital twin computing system to simulate various construction activities, which are likely to generate vibrations in the industrial floor. During construction, proactive noise cancellation systems can be deployed at identified locations to proactively reduce the generated noise. Embodiments of the present disclosure disclose analyzing the structural material properties, spring constant and other suitable factors to identify how the generated vibration will be propagated in the industrial floor and the distribution of noise in the industrial floor, so that proactive noise cancellation systems can be installed. Embodiments of the present disclosure disclose, based on the simulated noise generation from different parts of the industrial floor and relative position of various noise cancellation microphones, identifying the resultant noise. Embodiments of the present disclosure disclose determining whether the workers present inside the industrial floor need any personal noise cancellation system.

Embodiments of the present disclosure disclose systems and methods for vibration classification and reassignment. Embodiments of the present disclosure disclose identifying the vibration levels for the workers, while going in and out of the hazardous zone. Based on the identified types of the activities are to be executed in the industrial floor, the proposed system may classify the activities which will be generating noise, and accordingly the proposed system will be assigning the activities in such a way that, noise will be generated in the unmanned/automated section of the industrial floor, so that human workers are not impacted because of the generated noise. Embodiments of the present disclosure disclose systems and methods for selective noise cancellation. Based on the identified location of resonance, noise generation, and or vibration propagation direction, the proposed system may deploy noise cancellation systems at controlled locations to reduce noise generated by these activities.

Embodiments of the present disclosure disclose systems and methods for dynamic robot deployment. Embodiments of the present disclosure disclose using machine learning to determine anticipated worker activities that may generate noise. Embodiments of the present disclosure disclose determining the propagation of sound from the source of noise to other workers in vicinity which will result in exposure to above accepted levels. Embodiments of the present disclosure disclose determining robot placement to attenuate the sounds via different techniques depending on calculation of which will give the best noise reduction. Additionally, when no satisfactory noise reduction can be achieved under current environment, the example system may display a warning and in some embodiments a lockout. Embodiments of the present disclosure disclose performing digital twin simulation to identify which portion of an industrial floor will be generating vibration and hence noise. Embodiments of the present disclosure disclose proactively installing and remotely controlling a noise cancellation module.

Embodiments of the present disclosure disclose systems and methods for digital twin simulation from piezoelectric sensor analysis. For example, in any industrial shop floor, there can be different types of piezoelectric sensors installed to track generated vibration or noise in the surrounding. These piezoelectric sensors may measure the combined vibration and noise generated by different activities like drilling, hammering, etc. The location of piezoelectric sensors on the industrial floor may be identified using a digital twin simulation system. The digital twin simulation system may simulate activities inside the shop floor. The simulated vibration may match with piezoelectric sensor readings from predefined locations inside the factory. In case if there are any high noise generating activities going on in the factory, the proposed system may simulate these activities using the digital twin simulation system, and accordingly may identify suitable location for deploying noise cancellation microphones. In another example, the proposed system may monitor the piezoelectric sensors continuously to understand if there is any change in measurements (which indicates that something different has happened inside the industrial floor).

Embodiments of the present disclosure disclose systems and methods for vibration propagation simulation. In an example, if there is a high noise generating temporal activities going on inside the industrial floor, then the system can use the available information from digital twin simulation as well as using results from vibration propagation simulations to identify suitable locations for deploying noise cancellation microphones. In such a way, workers will not be affected with high level of noise. For example, the proposed system can simulate drilling inside the shop floor using digital twin simulation system. Based on the result (which represents noise plus vibration levels), it is possible to identify a suitable location for deploying noise cancellation microphones, so that workers will not be affected with high level of noise. In another example, the proposed system may look at multiple scenarios including worker protection and identification of industrial activities that require worker protection. The proposed system may identify suitable locations for deploying noise cancellation microphones, reassigning the industrial operations in order to reduce noise generation, etc. In some embodiments, the system can be deployed using advanced intelligent sensing systems which can be used for deploying safety devices inside the industrial environment. The system may continuously monitor different mobile sensors and easily identify activities taking place inside the industrial environment. Based on the digital twin simulation and analysis, the proposed system may identify which part of the machine is generating noise or can generate noise. In another example, the proposed system can be used to identify noise generation during the operation of different parts of the machine. For example, there could be different power converter attached to any machines. These power converters may generate lots of vibration and noise. The proposed system may identify how much noise these power converters are generating. The digital twin simulation may consider applied payload and assigned activity. The digital twin simulation may identify the levels of vibration or noise being generated.

Embodiments of the present disclosure disclose systems and methods for vibration maintenance analysis. Some noise can be addressed by performing proactive maintenance of the machine, while some noise will continue regardless of maintenance. The proposed system may consider the effect of different payload to identify if there is any risk for a person assigned a certain task. If there is a high vibration or noise being generated due to applied payload, then the proposed system can recommend that the machine must be serviced or other means be employed to address this issue, before assigning the task to a worker. The proposed system may look at different machine health parameters and mechanical integrity. Based on the different machine health parameters and mechanical integrity, the proposed system may recommend proactive maintenance schedule for the machine. For example, if some fault is identified in the current condition of the machine, then there may be high probability that there would be an issue with the machine during its operation, which can lead to worker injury. Machine condition monitoring techniques may be used to identify different machine health parameters in continuous mode. Based on these results recommender system will be identifying recommended maintenance schedule for the machines. This is done considering machine conditions, assigned tasks, applied payload etc.

Embodiments of the present disclosure disclose systems and methods for noise cancellation deployment. The proposed system may include noise-based cancellation modules, which may emit anti-noise (also referred as white noise) to neutralize the noise in the surrounding. The noise-based cancellation modules can be attached with the source of noise, in case of excessive noise being generated by the machine. The proposed system may identify different location where the sensors should be deployed in order to minimize the risk for workers assigned with high level activities. For example, when drilling or any other heavy-duty activity takes place inside the shop floor and there is a worker assigned for operating the machine, then the proposed system may recommend installation of safety devices such as noise cancellation sensors to nullify the effect of high noise levels. In an example, noise cancelling devices can also be dynamically positioned in the industrial floor based upon the digital twin simulation. These temporal noise cancelling devices can be deployed by the intelligent sensing system when the system identifies high noise level in a certain area. The digital twin computing system may identify various sources of vibration generation, and the properties of the vibration, such as its frequency and type, based on the calculated transfer function. These calculations can be used in generating appropriate anti-noise pulse to nullify the vibration.

Embodiments of the present disclosure disclose alternate embodiments of noise reduction in an industrial environment via dynamic robot deployment. For example, video captured from various cameras covering the complex can be analyzed, for example with YOLO (You Only Look Once) algorithm to perform object and people detection on the entire industrial work area. There may be multiple floors in some instances as construction work on one floor may induce noise or other potential hazards on adjacent areas above, below or on the other side of walls. As workers are navigating in different directions around the work area, their paths are mapped out by analyzing the differences in location detected between subsequent video frames. Embodiments of the present disclosure disclose detecting work context and worker's actions including picking up, placing down or getting ready to use a particular tool. Once a particular tool is detected, the acoustic profile of that tool may be used to determine the effect on nearby personnel before the tool is even turned on or used. For example, a circular saw of brand X may have a noise level of 89 decibels, while a jackhammer by brand Y may have a noise level of 95 decibels. The system may determine distance between tools and people using Euclidean metric on the bounding areas identified in the video. In an example, a tool operator may get an indication light either on the power tool itself or another safety device the operator will carry on. The indication may use a color code to indicate safety level of using the tool at the location they are currently at, considering the locations of all the other nearby workers. For example, green may indicate that the tool can safely be used immediately. Yellow may indicate that the tool operator should wait for robots to place enhanced noise protection. Red may indicate that it is not possible to reduce noise below accepted threshold via available means. Nearby personnel should be relocated to a safe distance before tool is used. In another example, a lockout can be implemented to prevent accidental tool operation in an unsafe scenario with nearby personnel exposed to excessive noise levels.

Embodiments of the present disclosure disclose deploying a robot to an optimized area determined by the digital twin model in order to attenuate the noise to all nearby personnel below the acceptable threshold. A robot can achieve this via multiple means which may be determined based on the effectiveness calculated via the digital twin modeling: deployable noise insulation panels placed in the sound path between a tool and nearby personnel, attenuation by dampening effect of vibration directly on material being worked on such as a robot rubber arm applying pressure on vibrating material, and active noise cancellation by intercepting the sound wave between the noise source and nearby personnel and generating a sound wave to cancel the sound wave. Embodiments of the present disclosure disclose warning and directing nearby bystanders which direction to move where they will be safe from loud sounds. Once the bystanders have been relocated, the red status shown to a tool operator may automatically go to green to indicate that the tool operator is safe to use the tool. Robots may also dynamically cordon off areas to prevent unaware personnel inadvertently walking in an unsafe noisy area.

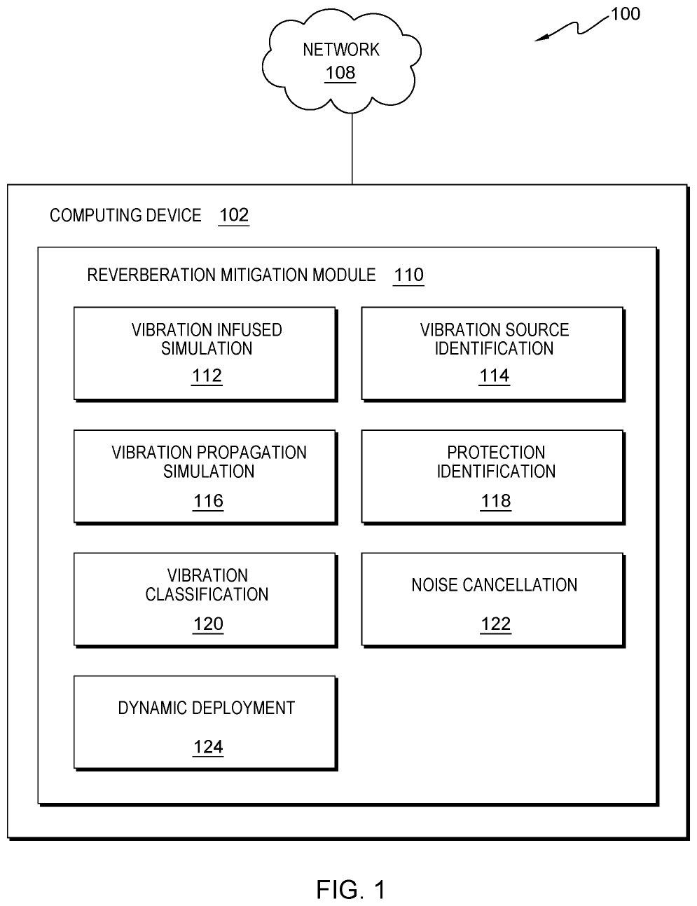

The present disclosure will now be described in detail with reference to the Figures. FIG. 1 is a functional block diagram illustrating a reverberation mitigation environment, generally designated 100, in accordance with an embodiment of the present disclosure.

In the depicted embodiment, reverberation mitigation environment 100 includes computing device 102 and network 108.

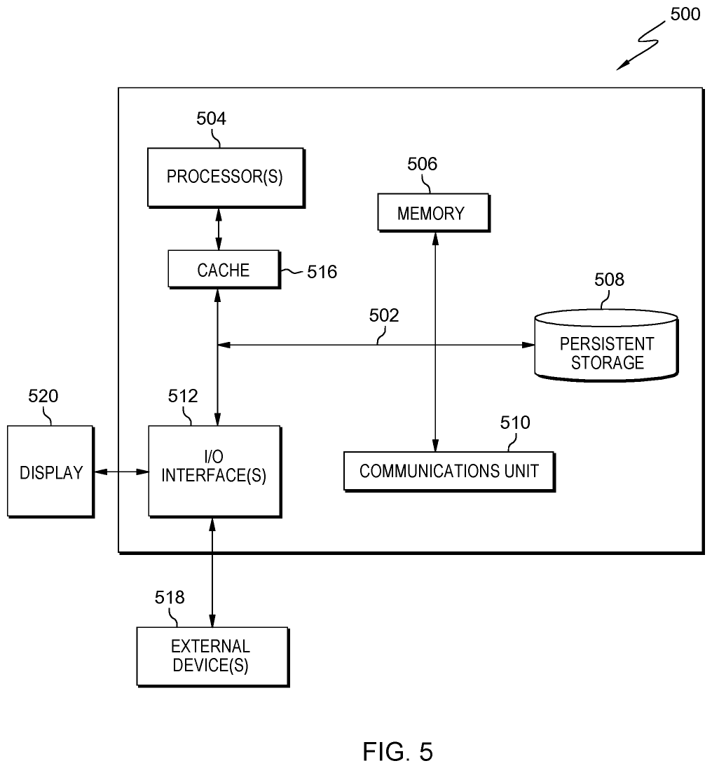

In various embodiments of the present disclosure, computing device 102 can be a laptop computer, a tablet computer, a netbook computer, a personal computer (PC), a desktop computer, a mobile phone, a smartphone, a smart watch, a wearable computing device, a personal digital assistant (PDA), or a server. In another embodiment, computing device 102 represents a computing system utilizing clustered computers and components to act as a single pool of seamless resources. In other embodiments, computing device 102 may represent a server computing system utilizing multiple computers as a server system, such as in a cloud computing environment. In general, computing device 102 can be any computing device or a combination of devices with access to reverberation mitigation module 110 and network 108 and is capable of processing program instructions and executing reverberation mitigation module 110, in accordance with an embodiment of the present disclosure. Computing device 102 may include internal and external hardware components, as depicted and described in further detail with respect to FIG. 5.

Further, in the depicted embodiment, computing device 102 includes reverberation mitigation module 110. In the depicted embodiment, reverberation mitigation module 110 is located on computing device 102. However, in other embodiments, reverberation mitigation module 110 may be located externally and accessed through a communication network such as network 108. The communication network can be, for example, a local area network (LAN), a wide area network (WAN) such as the Internet, or a combination of the two, and may include wired, wireless, fiber optic or any other connection known in the art. In general, the communication network can be any combination of connections and protocols that will support communications between computing device 102 and reverberation mitigation module 110, in accordance with a desired embodiment of the disclosure.

In one or more embodiments, reverberation mitigation module 110 is configured to generate a digital twin of an environment. The digital twin may be configured to simulate vibration within the environment based on equipment and activities within the environment that are simulated by the digital twin. For example, in an example industrial shop floor, there can be different types of sensors (e.g., piezoelectric sensors) installed to track generated vibration or noise in the surrounding. Reverberation mitigation module 110 may utilize the sensors to measure the combined vibration and noise generated by different activities like drilling, hammering etc. Reverberation mitigation module 110 may identify the location of the sensors inside the industrial floor using a digital twin simulation system. Reverberation mitigation module 110 may simulate activities inside the shop floor with the digital twin simulation system. The simulated vibration may match with sensor readings from predefined locations inside the factory. In case if there are any high noise generating activities going on in the factory, reverberation mitigation module 110 may simulate these activities using the digital twin simulation system. Reverberation mitigation module 110 may identify suitable location for deploying noise cancellation microphones. Reverberation mitigation module 110 may monitor the sensors continuously to understand if there is any change in measurements. In an example, the change in measurements may indicate that something different has happened inside the industrial floor.

In one or more embodiments, reverberation mitigation module 110 is configured to determine how vibration is propagated within the environment based on the simulated vibration generated by the digital twin. For example, if there is a high noise generating temporal activities going on inside an industrial floor, reverberation mitigation module 110 may use the available information from the digital twin simulation as well as using results from vibration propagation simulations to identify suitable locations for deploying noise cancellation microphones, so that workers will not be affected with high level of noise. For example, reverberation mitigation module 110 may simulate drilling inside the shop floor using the digital twin simulation system. Based on this result (which may represent noise plus vibration levels), reverberation mitigation module 110 may identify a suitable location for deploying noise cancellation microphones, so that workers will not be affected with high level of noise. In an example, reverberation mitigation module 110 may look at multiple scenarios including worker protection and identification of industrial activities that require worker protection. Reverberation mitigation module 110 may identify suitable locations for deploying noise cancellation microphones and may reassign the industrial operations to reduce noise generation. In an example, reverberation mitigation module 110 may deploy safety devices inside the industrial environment by using an advanced intelligent sensing system. Reverberation mitigation module 110 may continuously monitor different mobile sensors and may easily identify activities taking place inside the industrial environment. Based on the digital twin simulation and analysis, reverberation mitigation module 110 may identify which part of the machine is generating noise or can generate noise. Reverberation mitigation module 110 may identify noise generation during the operation of different parts of a machine. For example, there could be different power converter attached to a machine. These power converters may be capable of generating lot of vibration and noise. Reverberation mitigation module 110 may identify how much noise these power converters are generating. Reverberation mitigation module 110 may consider an applied payload and assigned activity and may accordingly identify the levels of vibration or noise being generated.

In one or more embodiments, reverberation mitigation module 110 is configured to generate a plan for mitigating the vibration for users within the environment. Reverberation mitigation module 110 may address some noise by performing proactive maintenance of the machine. In an example, reverberation mitigation module 110 may consider the effect of different payloads to identify if there is any risk for a user assigned a certain task. If there is a high vibration or noise being generated due to applied payload, reverberation mitigation module 110 may recommend that the machine must be serviced or other means be employed to address this issue, before assigning the task to a worker. Reverberation mitigation module 110 may look at different machine health parameters and mechanical integrity based on which reverberation mitigation module 110 may recommend proactive maintenance schedule for the machine. Accordingly, if some fault is identified in the current condition of the machine, then there is high probability that there would be an issue with the machine during its operation, which can lead to a worker injury. Reverberation mitigation module 110 may use machine condition monitoring techniques to identify different machine health parameters in a continuous mode. Based on these results, reverberation mitigation module 110 may identify recommended maintenance schedule for the machines. Reverberation mitigation module 110 may consider machine conditions, assigned tasks, and applied payload.

In one or more embodiments, reverberation mitigation module 110 is configured to determine at least one location to deploy a noise cancellation module within the environment. Reverberation mitigation module 110 may include one or more noise cancellation modules, which may emit anti-noise (also referred as white noise) to neutralize the noise in the surrounding. Reverberation mitigation module 110 may attach the one or more noise cancellation modules with the source of noise, in case of excessive noise being generated by the machine. Reverberation mitigation module 110 may identify different locations where the sensors should be deployed to minimize the risk for workers assigned with high level activities. For example, when drilling or any other heavy-duty activity takes place inside the shop floor and there is a worker assigned for operating the machine, reverberation mitigation module 110 may recommend installation of safety devices such as noise cancellation sensors to nullify the effect of high noise levels. In an example, a noise cancelling device can also be dynamically positioned in the industrial floor based upon the digital twin simulation. These temporal noise cancelling devices can be deployed by an intelligent sensing system when the system identifies high noise level in a certain area. Reverberation mitigation module 110 may identify various sources of vibration generation, and the properties of the vibration, such as its frequency and type, based on the calculated transfer function. Reverberation mitigation module 110 may use these calculations in generating appropriate anti-noise pulse to nullify the vibration.

In one or more embodiments, reverberation mitigation module 110 is configured to deploy a robot configured to attenuate the vibration in a determined location. Reverberation mitigation module 110 may analyze a video captured from various cameras covering an industrial environment to perform object and people detection on the entire industrial work area. This might be multiple floors in some instances as construction work on one floor may induce noise or other potential hazards on adjacent areas above, below or on the other side of walls. As workers may navigate in different directions around the work area, the paths of the workers may be mapped out by analyzing the differences in location detected between subsequent video frames. Reverberation mitigation module 110 may also detect work context and worker's actions including picking up, placing down or getting ready to use a particular tool. In an example, once a particular tool is detected, the acoustic profile of that tool will be used to determine the effect on nearby personnel before the tool is even turned on or used. For example, a circular saw of brand X may have a noise level of 89 decibels, while a jackhammer by brand Y may have a noise level of 95 decibels. Reverberation mitigation module 110 may determine distance between tools and people using a Euclidean metric on the bounding areas identified in the video.

In an example, reverberation mitigation module 110 may provide a tool operator an indication light either on the power tool itself or another safety device the operator will carry on. The indication may use a color code to indicate safety level of using the tool at the location they are currently at, considering the locations of all the other nearby workers. For example, green color may indicate that the tool can safely be used immediately. Yellow color may indicate that the tool operator should wait for robots to place enhanced noise protection. Red color may indicate that it is not possible to reduce noise below accepted threshold via available means. Nearby personnel should be relocated to a safe distance before the tool can be used. Reverberation mitigation module 110 may implement a lockout to prevent accidental tool operation in an unsafe scenario with nearby personnel exposed to an excessive noise level.

In another example, reverberation mitigation module 110 may deploy a robot to an optimized area determined by the digital twin model to attenuate the noise to all nearby personnel below the accepted threshold. Robots will be able to achieve this via multiple means which may be determined based on the effectiveness calculated via the digital twin modeling, e.g., deployable noise insulation panels placed in the sound path between a tool and nearby personnel, attenuation by dampening effect of vibration directly on material being worked on such as a robot rubber arm applying pressure on vibrating material, active noise cancellation by intercepting the sound wave between the noise source and nearby personnel and generating a sound wave to cancel the sound wave. In some embodiments, a robot may warn and direct nearby bystanders which direction to move where the bystanders will be safe from loud sounds and once the bystanders have been relocated, the red status shown to tool operator may automatically go to green to let them know that it is safe to use the tool. Robots may also dynamically cordon off areas to prevent unaware personnel inadvertently walking in an unsafe noisy area.

In some embodiments, within the spectrum of diverse types of sound, noises, and acoustic events, there may be various properties belonging to the audible sounds and can be classified as such. Reverberation mitigation module 110 may further select various types and colors of sound to further ameliorate the behavior and treatment for actions to be taken for an audible event. There can be four example types of sound: continuous noise, intermittent noise, impulsive noise, and low-frequency noise. Continuous noise may be produced continuously, for example, by machinery that keeps running without interruption. Continuous noise could come from factory equipment, engine noise, or heating and ventilation systems. Intermittent noise may be a noise level that increases and decreases rapidly. For example, intermittent noise might be caused by a train passing by, factory equipment that operates in cycles, or aircraft flying above a house. Impulsive noise may be commonly associated with the construction and demolition industry. These sudden bursts of noise can startle a user by the fast and surprising nature. Impulsive noises may be commonly created by explosions or construction equipment, such as pile drivers, or a next-door neighbor. Low-frequency noise may make up part of the fabric of people's daily soundscape. Whether low-frequency noise is the low background hum of a nearby power station or the roaring of large diesel engines, people may be exposed to low-frequency noise constantly. Low-frequency noise can be the hardest type of noise to reduce at source, so low-frequency noise can easily spread for miles around.

Further, in the depicted embodiment, reverberation mitigation module 110 includes vibration infused simulation 112, vibration identification 114, vibration propagation simulation 116, protection identification 118, vibration classification 120, noise cancellation 122 and dynamic deployment 124. In the depicted embodiment, vibration infused simulation 112, vibration identification 114, vibration propagation simulation 116, protection identification 118, vibration classification 120, noise cancellation 122 and dynamic deployment 124 are located on computing device 102 and reverberation mitigation module 110. However, in other embodiments, vibration infused simulation 112, vibration identification 114, vibration propagation simulation 116, protection identification 118, vibration classification 120, noise cancellation 122 and dynamic deployment 124 may be located externally and accessed through a communication network such as network 108.

In one or more embodiments, vibration infused simulation 112 is configured to simulate generation of vibrations from various parts of a work environment (e.g., while constructing or repairing any industrial floor). In an example, vibration infused simulation 112 may use a digital twin computing system to simulate generation of vibrations from various parts of the industrial floor. The various parts may include structures, machines, various activities, etc. Accordingly, vibration infused simulation 112 may generate a vibration pattern on a real time basis and aid in identifying the exact location of resonance, type of resonance etc.

In one or more embodiments, vibration identification 114 is configured to simulate various construction activities, which are likely to generate vibrations, for example, in the industrial floor. Accordingly, during construction, vibration identification 114 may proactively deploy a noise cancellation system at identified locations to proactively reduce the generated noise. In an example, vibration identification 114 may a digital twin computing system to simulate various construction activities.

In one or more embodiments, vibration propagation simulation 116 is configured to analyze, for example, structural material properties and spring constant, to identify how the generated vibration is propagated in a work environment (e.g., an industrial floor). Vibration propagation simulation 116 may identify the distribution of noise in the industrial floor, so that a proactive noise cancellation system can be installed. In an example, vibration propagation simulation 116 may use a digital twin simulation system to analyze structural material properties and spring constant etc. to identify how the generated vibration will be propagated in an industrial floor.

In one or more embodiments, protection identification 118 is configured to identify a resultant noise. Protection identification 118 may identify workers present inside the industrial floor who may need any personal noise cancellation system. In an example, protection identification 118 may identify the resultant noise based on the simulated noise generation from different parts of an industrial floor, and relative position of various noise cancellation microphones.

In one or more embodiments, vibration classification 120 is configured to identify the vibration levels for workers, while going in and out of a hazardous zone. Based on the identified types of the activities are to be executed in the industrial floor, vibration classification 120 may classify the activities which generate noise. Accordingly, vibration classification 120 may assign activities in such a way that, noise will be generated in the unmanned/automated section of the industrial floor, so that human workers may not be impacted because of the generated noise.

In one or more embodiments, noise cancellation 122 is configured to deploy a noise cancellation system at controlled locations in order to reduce noise generated by activities, based on the identified location of resonance, noise generation, and or vibration propagation direction etc.

In one or more embodiments, dynamic deployment 124 is configured to use a machine learning to determine anticipated worker activities that will generate noise. Dynamic deployment 124 may determine the propagation of sound from the source of noise to other workers in vicinity which will result in exposure to an accepted level. Dynamic deployment 124 may determine a robot placement to attenuate the sounds via different techniques depending on calculation of which will give the best noise reduction. Additionally, when no satisfactory noise reduction can be achieved under current environment, dynamic deployment 124 may display a warning and in some embodiments a lockout.

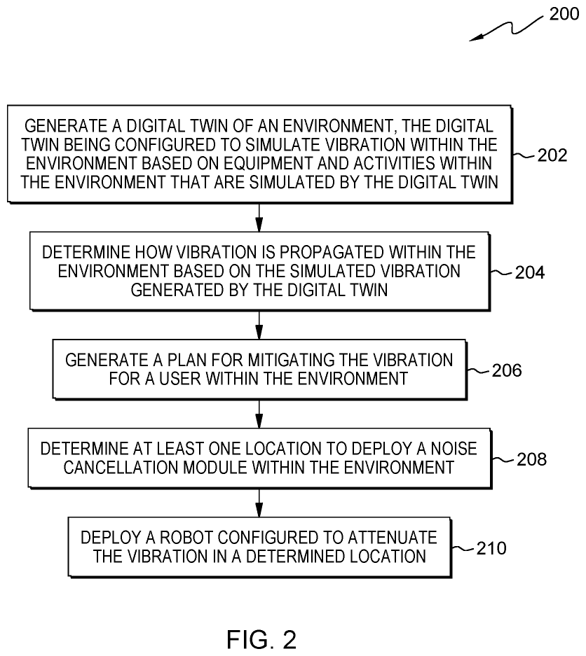

FIG. 2 is a flowchart 200 depicting operational steps of reverberation mitigation module 110 in accordance with an embodiment of the present disclosure.

Reverberation mitigation module 110 operates to generate a digital twin of an environment. The digital twin may be configured to simulate vibration within the environment based on equipment and activities within the environment that are simulated by the digital twin. Reverberation mitigation module 110 also operates to determine how vibration is propagated within the environment based on the simulated vibration generated by the digital twin. Reverberation mitigation module 110 operates to generate a plan for mitigating the vibration for users within the environment. Reverberation mitigation module 110 operates to determine at least one location to deploy a noise cancellation module within the environment. Reverberation mitigation module 110 may dynamically position the noise cancellation module in the environment based on the simulation vibration generated by the digital twin. Reverberation mitigation module 110 operates to deploy a robot configured to attenuate the vibration in a determined location. Reverberation mitigation module 110 may analyze a video captured from various cameras covering an industrial environment to perform object and people detection on the entire industrial work area. Reverberation mitigation module 110 may determine a distance between the equipment and the user using a Euclidean metric on a bounding area identified in a video.

In step 202, reverberation mitigation module 110 generates a digital twin of an environment. The digital twin may be configured to simulate vibration within the environment based on equipment and activities within the environment that are simulated by the digital twin. For example, in an example industrial shop floor, there can be different types of sensors (e.g., piezoelectric sensors) installed to track generated vibration or noise in the surrounding. Reverberation mitigation module 110 may utilize the sensors to measure the combined vibration and noise generated by different activities like drilling, hammering, etc. Reverberation mitigation module 110 may identify the location of the sensors inside the industrial floor using a digital twin simulation system. Reverberation mitigation module 110 may simulate activities inside the shop floor with the digital twin simulation system. The simulated vibration may match with sensor readings from predefined locations inside the factory. If there are any high noise generating activities going on in the factory, reverberation mitigation module 110 may simulate these activities using the digital twin simulation system. Reverberation mitigation module 110 may identify suitable location for deploying noise cancellation microphones. Reverberation mitigation module 110 may monitor the sensors continuously to understand if there is any change in measurements. In an example, the change in measurements may indicate that something different has happened inside the industrial floor. In an example, reverberation mitigation module 110 may track the generated vibration with one or more piezoelectric sensor. Reverberation mitigation module 110 may measure the combined vibration and noise generated by different activities.

In step 204, reverberation mitigation module 110 determines how vibration is propagated within the environment based on the simulated vibration generated by the digital twin. For example, if there is a high noise generating temporal activities going on inside an industrial floor, reverberation mitigation module 110 may use the available information from the digital twin simulation as well as using results from vibration propagation simulations to identify suitable locations for deploying noise cancellation microphones, so that workers will not be affected with high level of noise. For example, reverberation mitigation module 110 may simulate drilling inside the shop floor using the digital twin simulation system. Based on this result (which may represent noise plus vibration levels), reverberation mitigation module 110 may identify a suitable location for deploying noise cancellation microphones, so that workers will not be affected by high levels of noise. In an example, reverberation mitigation module 110 may look at multiple scenarios including worker protection and identification of industrial activities that require worker protection. Reverberation mitigation module 110 may identify suitable locations for deploying noise cancellation microphones and may reassign the industrial operations to reduce noise generation. In an example, reverberation mitigation module 110 may deploy safety devices inside the industrial environment by using an advanced intelligent sensing system. Reverberation mitigation module 110 may continuously monitor different mobile sensors and may easily identify activities taking place inside the industrial environment. Based on the digital twin simulation and analysis, reverberation mitigation module 110 may identify which part of the machine is generating noise or can generate noise. Reverberation mitigation module 110 may identify noise generation during the operation of different parts of a machine. For example, there could be different power converters attached to a machine. These power converters may be capable of generating lots of vibration and noise. Reverberation mitigation module 110 may identify how much noise these power converters are generating. Reverberation mitigation module 110 may consider an applied payload and assigned activity and may accordingly identify the levels of vibration or noise being generated.

In step 206, reverberation mitigation module 110 generates a plan for mitigating the vibration for users within the environment. Reverberation mitigation module 110 may address some noise by performing proactive maintenance of the machine. In an example, reverberation mitigation module 110 may consider the effect of different payloads to identify if there is any risk for a user assigned a certain task. If there is a high vibration or noise being generated due to applied payload, reverberation mitigation module 110 may recommend that the machine must be serviced or other means be employed to address this issue, before assigning the task to a worker. Reverberation mitigation module 110 may look at different machine health parameters and mechanical integrity based on which reverberation mitigation module 110 may recommend proactive maintenance schedule for the machine. This means that if some fault is identified in the current condition of the machine, then there is high probability that there would be an issue with the machine during its operation, which can lead to a worker injury. Reverberation mitigation module 110 may use machine condition monitoring techniques to identify different machine health parameters in a continuous mode. Based on these results, reverberation mitigation module 110 may identify recommended maintenance schedule for the machines. Reverberation mitigation module 110 may consider machine conditions, assigned tasks, and applied payload.

In step 208, reverberation mitigation module 110 determines at least one location to deploy a noise cancellation module within the environment. Reverberation mitigation module 110 may dynamically position the noise cancellation module in the environment based on the simulation vibration generated by the digital twin. Reverberation mitigation module 110 may include one or more noise cancellation modules, which may emit anti-noise (also referred as white noise) to neutralize the noise in the surrounding. Reverberation mitigation module 110 may attach the one or more noise cancellation modules with the source of noise, in case of excessive noise being generated by the machine. Reverberation mitigation module 110 may identify one or more sources of the generated vibration and the properties of the vibration. Reverberation mitigation module 110 may identify different locations where the sensors should be deployed to minimize the risk for workers assigned with high level activities. For example, when drilling or any other heavy-duty activity takes place inside the shop floor and there is a worker assigned for operating the machine, reverberation mitigation module 110 may recommend installation of safety devices such as noise cancellation sensors to nullify the effect of high noise levels. In an example, a noise cancelling device can also be dynamically positioned in the industrial floor based upon the digital twin simulation. These temporal noise cancelling devices can be deployed by an intelligent sensing system when the system identifies high noise level in a certain area. Reverberation mitigation module 110 may identify various sources of vibration generation, and the properties of the vibration, such as its frequency and type, based on the calculated transfer function. Reverberation mitigation module 110 may use these calculations in generating appropriate anti-noise pulse to nullify the vibration.

In step 210, reverberation mitigation module 110 deploys a robot configured to attenuate the vibration in a determined location. Reverberation mitigation module 110 may analyze a video captured from various cameras covering an industrial environment to perform object and people detection on the entire industrial work area. Reverberation mitigation module 110 may determine a distance between the equipment and the user using a Euclidean metric on a bounding area identified in a video. Reverberation mitigation module 110 may deploy the robot to the determined location based on effectiveness calculated by the digital twin. This might be multiple floors in some instances as construction work on one floor may induce noise or other potential hazards on adjacent areas above, below or on the other side of walls. As workers may navigate in different directions around the work area, the paths of the workers may be mapped out by analyzing the differences in location detected between subsequent video frames. Reverberation mitigation module 110 may also detect work context and worker's actions including picking up, placing down or getting ready to use a particular tool. In an example, once a particular tool is detected, the acoustic profile of that tool will be used to determine the effect on nearby personnel before the tool is even turned on or used. For example, a circular saw of brand X may have a noise level of 89 decibels, while a jackhammer by brand Y may have a noise level of 95 decibels. Reverberation mitigation module 110 may determine distance between tools and people using a Euclidean metric on the bounding areas identified in the video.

In an example, reverberation mitigation module 110 may provide a tool operator an indication light either on the power tool itself or another safety device the operator will carry on. The indication may use a color code to indicate safety level of using the tool at the location they are currently at, considering the locations of all the other nearby workers. For example, green color may indicate that the tool can safely be used immediately. Yellow color may indicate that the tool operator should wait for robots to place enhanced noise protection. Red color may indicate that it is not possible to reduce noise below accepted threshold via available means. Nearby personnel should be relocated to a safe distance before the tool can be used. Reverberation mitigation module 110 may implement a lockout to prevent accidental tool operation in an unsafe scenario with nearby personnel exposed to an excessive noise level.

In another example, reverberation mitigation module 110 may deploy a robot to an optimized area determined by the digital twin model to attenuate the noise to all nearby personnel below the accepted threshold. Robots will be able to achieve this via multiple means which may be determined based on the effectiveness calculated via the digital twin modeling, e.g., deployable noise insulation panels placed in the sound path between a tool and nearby personnel, attenuation by dampening effect of vibration directly on material being worked on such as a robot rubber arm applying pressure on vibrating material, active noise cancellation by intercepting the sound wave between the noise source and nearby personnel and generating a sound wave to cancel the sound wave. In some embodiments, a robot may warn and direct nearby bystanders which direction to move where the bystanders will be safe from loud sounds and once the bystanders have been relocated, the red status shown to tool operator may automatically go to green to let them know that it is safe to use the tool. Robots may also dynamically cordon off areas to prevent unaware personnel inadvertently walking in an unsafe noisy area.

In some embodiments, within the spectrum of diverse types of sound, noises, and acoustic events, there may be various properties belonging to the audible sounds and can be classified as such. Reverberation mitigation module 110 may further select various types and colors of sound to further ameliorate the behavior and treatment for actions to be taken for an audible event. There can be four example types of sound: continuous noise, intermittent noise, impulsive noise, and low-frequency noise. Continuous noise may be produced continuously, for example, by machinery that keeps running without interruption. Continuous noise could come from factory equipment, engine noise, or heating and ventilation systems. Intermittent noise may be a noise level that increases and decreases rapidly. For example, intermittent noise might be caused by a train passing by, factory equipment that operates in cycles, or aircraft flying above a house. Impulsive noise may be commonly associated with the construction and demolition industry. These sudden bursts of noise can startle a user by the fast and surprising nature. Impulsive noises may be commonly created by explosions or construction equipment, such as pile drivers, or a next-door neighbor. Low-frequency noise may make up part of the fabric of people's daily soundscape. Whether low-frequency noise is the low background hum of a nearby power station or the roaring of large diesel engines, people may be exposed to low-frequency noise constantly. Low-frequency noise can be the hardest type of noise to reduce at source, so low-frequency noise can easily spread for miles around.

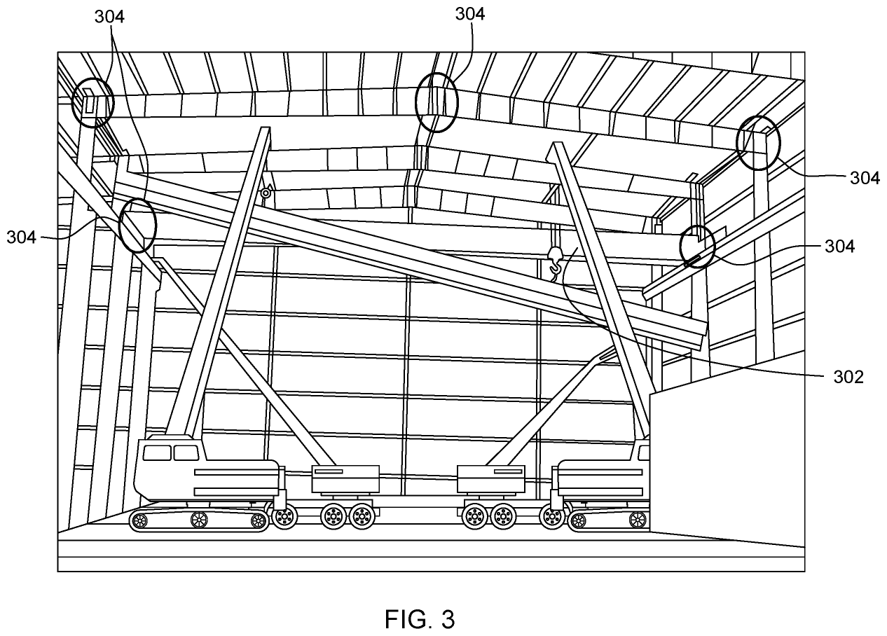

FIG. 3 illustrates an exemplary operation environment of reverberation mitigation module 110, in accordance with an embodiment of the present disclosure.

In the example of FIG. 3, while any construction is being performed in any industrial floor 302, reverberation mitigation module 110 may perform digital twin simulation to identify which portion (e.g., source 304) of the industrial floor will be generating vibration and hence noise. Reverberation mitigation module 110 may arrange to proactively install one or more noise cancellation modules at source 304 so that noise can be reduced in the working environment. Reverberation mitigation module 110 may remotely control the noise cancellation module at source 304.

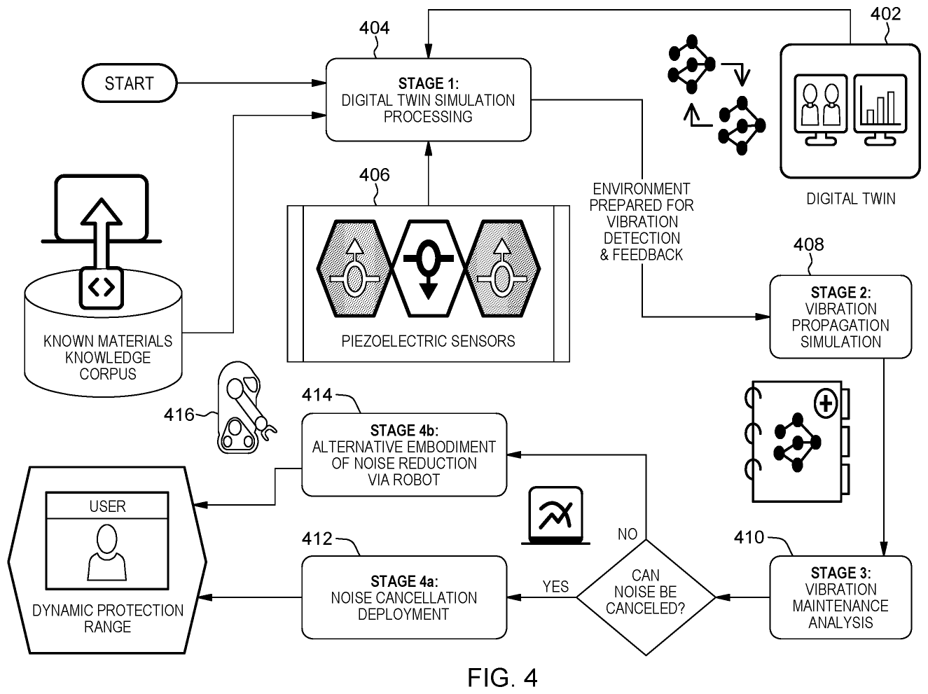

FIG. 4 illustrates exemplary functional diagram and operational steps of reverberation mitigation module 110, in accordance with an embodiment of the present disclosure.

In the example of FIG. 4, reverberation mitigation module 110 may generate digital twin 402 of an environment. Digital twin 402 may be configured to simulate vibration within the environment based on equipment and activities within the environment that are simulated by digital twin 402. At block 404, reverberation mitigation module 110 may perform digital twin simulation from piezoelectric sensor analysis. For example, in an example industrial shop floor, there can be different types of sensors (e.g., piezoelectric sensors 406) installed to track generated vibration or noise in the surrounding. Reverberation mitigation module 110 may utilize piezoelectric sensors 406 to measure the combined vibration and noise generated by different activities like drilling, hammering etc. Reverberation mitigation module 110 may identify the location of the sensors inside the industrial floor. Reverberation mitigation module 110 may simulate activities inside the shop floor. Reverberation mitigation module 110 may match with sensor readings from predefined locations inside the factory. Reverberation mitigation module 110 may monitor piezoelectric sensors 406 continuously to understand if there is any change in measurements which may indicate that something different has happened inside the industrial floor.

At block 408, reverberation mitigation module 110 may perform vibration propagation simulation. Reverberation mitigation module 110 may determine how vibration is propagated within the environment based on the simulated vibration generated by digital twin 402. For example, if there is a high noise generating temporal activities going on inside an industrial floor, reverberation mitigation module 110 may use the available information from the digital twin simulation as well as using results from vibration propagation simulations to identify suitable locations for deploying noise cancellation microphones, so that workers will not be affected with high level of noise. For example, reverberation mitigation module 110 may simulate drilling inside the shop floor using the digital twin simulation system. Based on this result (which may represent noise plus vibration levels), reverberation mitigation module 110 may identify a suitable location for deploying noise cancellation microphones, so that workers will not be affected with high level of noise. In an example, reverberation mitigation module 110 may look at multiple scenarios including worker protection and identification of industrial activities that require worker protection. Reverberation mitigation module 110 may identify suitable locations for deploying noise cancellation microphones and may reassign the industrial operations to reduce noise generation.

At block 410, reverberation mitigation module 110 may perform vibration maintenance analysis. Reverberation mitigation module 110 may generate a plan for mitigating the vibration for users within the environment. Reverberation mitigation module 110 may address some noise by performing proactive maintenance of the machine. In an example, reverberation mitigation module 110 may consider the effect of different payloads to identify if there is any risk for a user assigned a certain task. If there is a high vibration or noise being generated due to applied payload, reverberation mitigation module 110 may recommend that the machine must be serviced or other means be employed to address this issue, before assigning the task to a worker. Reverberation mitigation module 110 may look at different machine health parameters and mechanical integrity based on which reverberation mitigation module 110 may recommend proactive maintenance schedule for the machine. Reverberation mitigation module 110 may use machine condition monitoring techniques to identify different machine health parameters in a continuous mode. Based on these results, reverberation mitigation module 110 may identify recommended maintenance schedule for the machines. Reverberation mitigation module 110 may consider machine conditions, assigned tasks, and applied payload.

At block 412, reverberation mitigation module 110 may perform noise cancellation deployment. Reverberation mitigation module 110 may determine at least one location to deploy a noise cancellation module within the environment. Reverberation mitigation module 110 may include one or more noise cancellation modules, which may emit anti-noise (also referred as white noise) to neutralize the noise in the surrounding. Reverberation mitigation module 110 may attach the one or more noise cancellation modules with the source of noise, in case of excessive noise being generated by the machine. Reverberation mitigation module 110 may identify different locations where the sensors should be deployed to minimize the risk for workers assigned with high level activities. For example, when drilling or any other heavy-duty activity takes place inside the shop floor and there is a worker assigned for operating the machine, reverberation mitigation module 110 may recommend installation of safety devices such as noise cancellation sensors to nullify the effect of high noise levels.

At block 414, reverberation mitigation module 110 may deploy robot 416 configured to attenuate the vibration in a determined location. Reverberation mitigation module 110 may analyze a video captured from various cameras covering an industrial environment to perform object and people detection on the entire industrial work area. As workers may navigate in different directions around the work area, the paths of the workers may be mapped out by analyzing the differences in location detected between subsequent video frames. Reverberation mitigation module 110 may also detect work context and worker's actions including picking up, placing down or getting ready to use a particular tool. In an example, once a particular tool is detected, the acoustic profile of that tool will be used to determine the effect on nearby personnel before the tool is even turned on or used.

FIG. 5 depicts a block diagram 500 of components of computing device 102 in accordance with an illustrative embodiment of the present disclosure. It should be appreciated that FIG. 5 provides only an illustration of one implementation and does not imply any limitations with regard to the environments in which different embodiments may be implemented. Many modifications to the depicted environment may be made.

Computing device 102 may include communications fabric 502, which provides communications between cache 516, memory 506, persistent storage 508, communications unit 510, and input/output (I/O) interface(s) 512. Communications fabric 502 can be implemented with any architecture designed for passing data and/or control information between processors (such as microprocessors, communications and network processors, etc.), system memory, peripheral devices, and any other hardware components within a system. For example, communications fabric 502 can be implemented with one or more buses or a crossbar switch.

Memory 506 and persistent storage 508 are computer readable storage media. In this embodiment, memory 506 includes random access memory (RAM). In general, memory 506 can include any suitable volatile or non-volatile computer readable storage media. Cache 516 is a fast memory that enhances the performance of computer processor(s) 504 by holding recently accessed data, and data near accessed data, from memory 506.

Reverberation mitigation module 110 may be stored in persistent storage 508 and in memory 506 for execution by one or more of the respective computer processors 504 via cache 516. In an embodiment, persistent storage 508 includes a magnetic hard disk drive. Alternatively, or in addition to a magnetic hard disk drive, persistent storage 508 can include a solid state hard drive, a semiconductor storage device, read-only memory (ROM), erasable programmable read-only memory (EPROM), flash memory, or any other computer readable storage media that is capable of storing program instructions or digital information.

The media used by persistent storage 508 may also be removable. For example, a removable hard drive may be used for persistent storage 508. Other examples include optical and magnetic disks, thumb drives, and smart cards that are inserted into a drive for transfer onto another computer readable storage medium that is also part of persistent storage 508.

Communications unit 510, in these examples, provides for communications with other data processing systems or devices. In these examples, communications unit 510 includes one or more network interface cards. Communications unit 510 may provide communications through the use of either or both physical and wireless communications links. Reverberation mitigation module 110 may be downloaded to persistent storage 508 through communications unit 510.

I/O interface(s) 512 allows for input and output of data with other devices that may be connected to computing device 102. For example, I/O interface 512 may provide a connection to external devices 518 such as a keyboard, keypad, a touch screen, and/or some other suitable input device. External devices 518 can also include portable computer readable storage media such as, for example, thumb drives, portable optical or magnetic disks, and memory cards. Software and data used to practice embodiments of the present invention, e.g., reverberation mitigation module 110 can be stored on such portable computer readable storage media and can be loaded onto persistent storage 508 via I/O interface(s) 512. I/O interface(s) 512 also connect to display 520.

Display 520 provides a mechanism to display data to a user and may be, for example, a computer monitor.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Python, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

What is claimed is:

1. A computer-implemented method comprising:
generating, by one or more processors, a digital twin of an environment, wherein the digital twin simulates vibration within the environment based on equipment and activities within the environment that are simulated by the digital twin;
determining, by one or more processors, how vibration is propagated within the environment based on the simulated vibration generated by the digital twin; and
generating, by one or more processors, a plan for mitigating the vibration for a user within the environment.

2. The computer-implemented method of claim 1, wherein the plan for mitigating the vibration includes determining at least one location to deploy a noise cancellation module within the environment.

3. The computer-implemented method of claim 2, further comprising:
dynamically positioning, by one or more processors, the noise cancellation module in the environment based on the simulation vibration generated by the digital twin.

4. The computer-implemented method of claim 2, further comprising:
identifying, by one or more processors, one or more sources of the generated vibration and the properties of the vibration.

5. The computer-implemented method of claim 1, wherein the plan for mitigating the vibration includes deploying a robot attenuating the vibration in a determined location.

6. The computer-implemented method of claim 5, further comprising:
determining, by one or more processors, a distance between the equipment and the user using a Euclidean metric on a bounding area identified in a video; and
deploying, by one or more processors, the robot to the determined location based on effectiveness calculated by the digital twin.

7. The computer-implemented method of claim 1, further comprising:
tracking, by one or more processors, the generated vibration with one or more piezoelectric sensors; and
measuring, by one or more processors, combined vibration and noise generated by different activities.

8. A computer program product comprising:
one or more computer readable storage media, and program instructions collectively stored on the one or more computer readable storage media, the program instructions comprising:
program instructions to generate a digital twin of an environment, wherein the digital twin simulates vibration within the environment based on equipment and activities within the environment that are simulated by the digital twin;
program instructions to determine how vibration is propagated within the environment based on the simulated vibration generated by the digital twin; and
program instructions to generate a plan for mitigating the vibration for a user within the environment.

9. The computer program product of claim 8, wherein the plan for mitigating the vibration includes determining at least one location to deploy a noise cancellation module within the environment.

10. The computer program product of claim 9, further comprising:
program instructions to dynamically position the noise cancellation module in the environment based on the simulation vibration generated by the digital twin.

11. The computer program product of claim 9, further comprising:
program instructions to identify one or more sources of the generated vibration and the properties of the vibration.

12. The computer program product of claim 8, wherein the plan for mitigating the vibration includes deploying a robot attenuating the vibration in a determined location.

13. The computer program product of claim 12, further comprising:
program instructions to determine a distance between the equipment and the user using a Euclidean metric on a bounding area identified in a video; and
program instructions to deploy the robot to the determined location based on effectiveness calculated by the digital twin.

14. The computer program product of claim 8, further comprising:
program instructions to track the generated vibration with one or more piezoelectric sensors; and
program instructions to measure combined vibration and noise generated by different activities.

15. A computer system comprising:
one or more computer processors, one or more computer readable storage media, and program instructions stored on the one or more computer readable storage media for execution by at least one of the one or more computer processors, the program instructions comprising:
program instructions to generate a digital twin of an environment, wherein the digital twin simulates vibration within the environment based on equipment and activities within the environment that are simulated by the digital twin;
program instructions to determine how vibration is propagated within the environment based on the simulated vibration generated by the digital twin; and
program instructions to generate a plan for mitigating the vibration for a user within the environment.

16. The computer system of claim 15, wherein the plan for mitigating the vibration includes determining at least one location to deploy a noise cancellation module within the environment.

17. The computer system of claim 16, further comprising:
program instructions to dynamically position the noise cancellation module in the environment based on the simulation vibration generated by the digital twin.

18. The computer system of claim 16, further comprising:
program instructions to identify one or more sources of the generated vibration and the properties of the vibration.

19. The computer system of claim 15, wherein the plan for mitigating the vibration includes deploying a robot attenuating the vibration in a determined location.

20. The computer system of claim 19, further comprising:
program instructions to determine a distance between the equipment and the user using a Euclidean metric on a bounding area identified in a video; and
program instructions to deploy the robot to the determined location based on effectiveness calculated by the digital twin.
